(19) United States
(12) Patent Application Publication
(10) Pub. No.: US 2013/0069242 A1
(43) Pub. Date: Mar. 21, 2013

(54) ARRANGEMENT OF THROUGH-SUBSTRATE VIAS FOR STRESS RELIEF AND IMPROVED DENSITY

(71) Applicants: Ping-Yung YUH, New Taipei City (TW); Cheng-I Huang, Hsinchu City (TW); Chung-Hsing Wang, Baoshan Township (TW)

(72) Inventors: Ping-Yung YUH, New Taipei City (TW); Cheng-I Huang, Hsinchu City (TW); Chung-Hsing Wang, Baoshan Township (TW)

(73) Assignee: Taiwan Semiconductor Manufacturing Co., Ltd., Hsin-Chu (TW)

(21) Appl. No.: 13/237,387

(22) Filed: Sep. 20, 2011

(51) Int. Cl. H01L 23/48

(52) U.S. Cl. 257/774; 257/E23.011

(57) ABSTRACT

A semiconductor device structure for a three-dimensional integrated circuit has a semiconductor substrate having a plurality of through-substrate vias provided in the substrate, wherein three or more of the plurality of through-substrate vias are arranged in a hexagonal packing array with respect to their design-rule circle.

### FIELD

The disclosed subject matter relates generally to integrated circuits and more particularly to through-substrate vias.

### BACKGROUND

Through-silicon vias (TSVs) are often used in 3D integrated circuit devices and stacked integrated circuit dies for connecting dies. Integrated circuit (IC) dies are generally formed on semiconductor wafer substrates, such as silicon wafers, and the TSVs extend through the thickness of the wafer substrate extending from one side of the substrate to the other side, thus, connecting the integrated circuits on a die to the backside of the die. Because the TSVs are metal vias extending through the thickness of the semiconductor substrate, the presence of the TSVs create residual tensile stress in the surrounding semiconductor material. This requires that the TSVs are kept at a distance apart from device circuits in the semiconductor wafer in order to avoid degrading the device circuits' performance. The necessity to keep the device circuits away from the TSVs defines a region around a given TSV in which no device circuits are placed and the region is referred to as a keep-out zone.

The size of the keep-out zone around TSVs depends on the semiconductor devices' performance degradation tolerance and, thus, it is not a fixed size. If the device's performance requirement can tolerate higher degradation (i.e. has a high tolerance), the keep-out zone can be smaller. If the device has a low tolerance, the keep-out zone would be larger. For example, if the device can tolerate 5% degradation in performance, the keep-out zone may be as small as the area within 5 μm from a TSV. If the device can only tolerate 1% degradation in performance, the keep-out zone would need to be larger to keep the device circuits and the TSVs apart. In any event, the keep-out zones around TSVs reduce the amount of semiconductor substrate area available for the device circuitry placement. Therefore, conventionally, the more TSVs a semiconductor substrate requires, the aggregated size of the keep-out zones will be larger and the amount of semiconductor substrate area available for device circuits will be smaller. The keep-out zones can be any shape, like a rectangle or a rectangular region.

In addition to the keep-out zones, TSVs have other electrical and/or physical rules that define the minimum spacing between any two TSVs, which are referred to as a design-rule circle for a TSV. For a given design rule having a defined TSV diameter, the design-rule circle has a fixed diameter defined from the center of a TSV. The keep-out zone and the design-rule circle present a restriction on the IC device circuit layout designs to meet the goal of maximum TSV density, maximum silicon area utilization rate, and maximum wiring routability.

In currently practiced layouts for a semiconductor wafer substrate, the TSVs are arranged on a square grid on the whole chip with device circuits being placed nearby, which suffers from low density of TSVs, poor routability of wiring features that connect to the TSVs, as well as low silicon utilization rate, since the total area of keep-out-zone is very large.

### BRIEF DESCRIPTION OF THE DRAWINGS

FIG. 1A is a schematic illustration of a top-down view of a portion of a semiconductor wafer substrate containing TSVs arranged in a conventional manner.

FIG. 1B is a schematic illustration of TSVs arranged in a conventional manner illustrating the conventional arrangement's limited wiring routability.

FIG. 2 is a schematic illustration of a top-down view of a portion of a semiconductor wafer substrate containing TSVs arranged according to an embodiment of the present disclosure.

FIG. 3 is a schematic illustration of a top-down view of a semiconductor wafer substrate showing the grouped placements of TSVs according to another embodiment.

The drawings are schematic and the features illustrated therein are not drawn to scale.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

According to an embodiment, a semiconductor device structure for a three-dimensional integrated circuit is disclosed. The semiconductor device structure comprises a semiconductor substrate having a plurality of through-substrate vias provided in the substrate, wherein three or more of the plurality of through-substrate vias are arranged in a hexagonal packing array with respect to their design-rule circle.

As used herein, the term “through-substrate via” is used to refer to structures commonly referred in the art as through-silicon vias and is intended to also include similar through-via structure that may be provided in semiconductor wafer substrates that are made of semiconductor materials other than silicon, such as GaAs. Accordingly, the acronym “TSVs” is used herein to refer to both “through-silicon vias” as well as “through-substrate vias.”

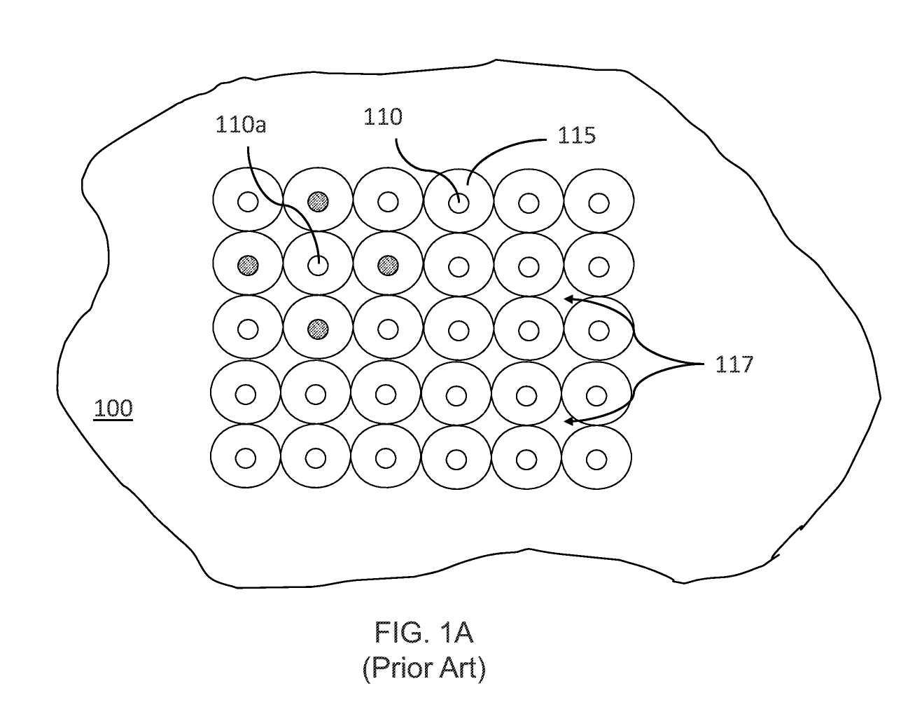

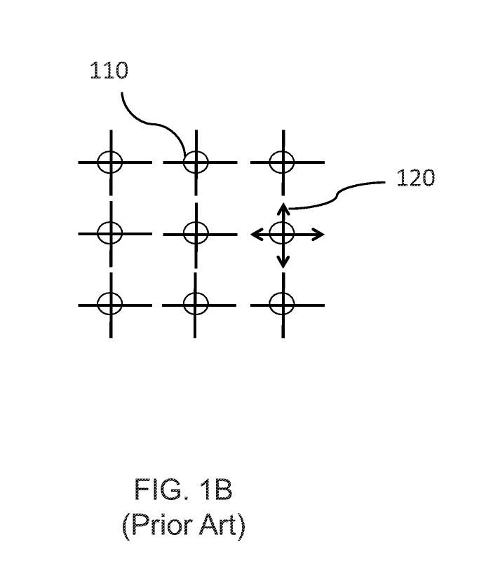

FIG. 1A shows a schematic top-down view of a portion of a semiconductor wafer substrate 100 containing a plurality of TSVs 110 arranged in a conventional manner. The TSVs 110 are arranged in a mesh-like square-grid array. The TSVs are shown with their design-rule circles 115. The TSVs are positioned so that the design-rule circles 115 touch each other but they cannot overlap one another. Thus, the minimum distance between two closest neighbor TSVs is equal to the diameter of the design-rule circle. The illustration shows that the conventional square-grid array arrangement has substantial amount of wasted area 117 which potentially can be used for other TSVs if the TSVs can be arranged with higher density.

FIG. 1B shows another limitation of the conventional square-grid arrangement of TSVs 110. For each TSV, four possible wiring routing directions identified by the arrows 120 are blocked by each other and, thus, the arrangement has a limited wiring routability.

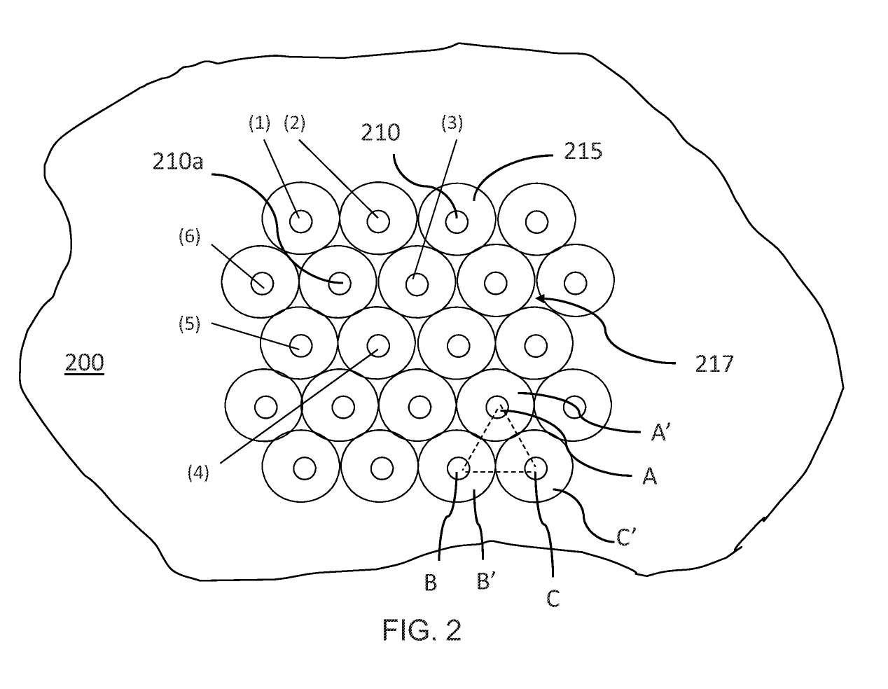

FIG. 2 shows a schematic illustration of a top-down view of a portion of a semiconductor wafer substrate 200 containing TSVs 210 arranged according to an embodiment of the present disclosure. In the semiconductor wafer substrate 200, the TSVs 210 are arranged in a hexagonal packing array. The TSVs 210 are shown with their design-rule circles 215. The TSVs 210 in this hexagonal packing array provides the densest packing arrangement for the TSVs 210. “Hexagonal packing array” as used herein refers to the arrangement of the TSVs where three adjacent TSVs are arranged as close to each other as possible. This means that the design-rule circles for the three adjacent TSVs are tangent to each other, or just touching each other without overlapping one another. In the hexagonal packing arrangement, the centers of any three adjacent TSVs would form the vertices of an equilateral triangle so that line segments connecting the centers of the three adjacent TSVs form an equilateral triangle. For example, consider the three adjacent TSVs identified in FIG. 2 as A, B and C. Their design-rule circles A′, B′ and C′ are tangent to one another and the centers of the three TSVs form an equilateral triangle. As a result, a given TSV 210a, for example, has a maximum of six possible closest neighbor TSVs (1), (2), (3), (4), (5) and (6). As mentioned above, closest neighbor TSVs are those neighboring TSVs whose design-rule circles are touching each other, i.e., at their minimum possible spacing. In comparison, in the conventional TSV arrangement shown in FIG. 1A, a given TSV 110a has a maximum of only four possible closest neighbor TSVs.

Unlike the conventional square-grid array of TSVs shown in FIG. 1A, the hexagonal packing array of TSVs in FIG. 2 provides a higher density TSVs arrangement resulting in substantially less wasted area 217. Accordingly, the TSV arrangement according to the present disclosure provides more number of TSVs within the same area than conventional square-grid array can.

In some embodiments, TSVs are provided in interposer substrates that do not have any active device circuitry in the semiconductor wafer substrate. Therefore, the stress effect of TSVs to device circuitry does not exist and the densest TSV packing is possible. However, in embodiments where the TSVs are provided in a semiconductor wafer substrate on which active IC dies are also provided, the keep-out zones around each TSV or each group of TSVs where IC device circuitry cannot be placed limits where the IC device circuitry can be placed in the wafer substrate. Placing TSV on the whole chip leads to large keep-out zone, which decreases the silicon utilization area.

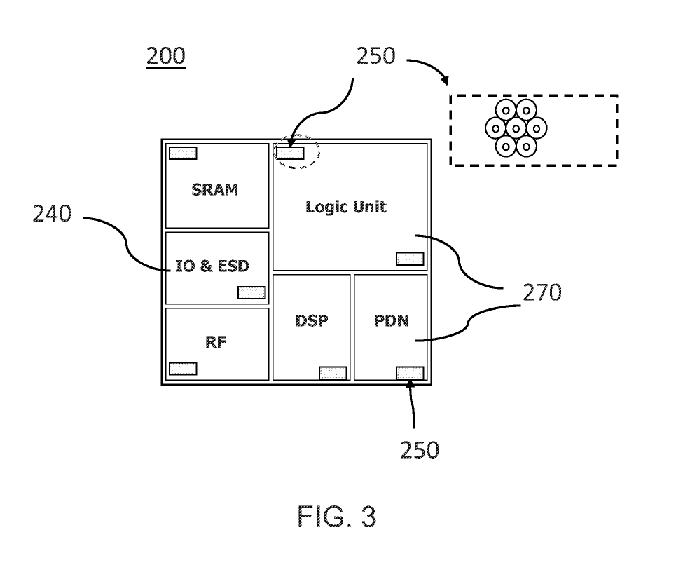

Referring to FIG. 3, according to another embodiment, the TSVs are grouped and positioned within one or more TSV sites 250 in an IC die portion 240 on the wafer substrate 200 wherein in each of the TSV sites 250, there are no active integrated circuits in the substrate. As shown, the one or more TSV sites 250 can be positioned within various integrated circuit areas 270 within a given IC die portion 240 but there are no active integrated circuits inside the TSV sites 250. By grouping as many of the TSVs into the one or more TSV sites 250, the deleterious effect from TSVs' residual stress on the integrated circuits outside the TSV site can be reduced or eliminated by overlapping the keep-out zone of each individual TSV and, thus, reducing the overall size of the keep-out-zones in the aggregate. This further reduces or eliminates any deleterious effects from TSVs' residual stress on the integrated circuits.

Although the subject matter has been described in terms of exemplary embodiments, it is not limited thereto. Rather, the appended claims should be construed broadly, to include other variants and embodiments, which may be made by those skilled in the art.

What is claimed is:

1. A semiconductor device structure for a three-dimensional integrated circuit, comprising:
a semiconductor substrate having a plurality of through-substrate vias provided in the substrate;
wherein three or more of the plurality of through-substrate vias are arranged in a hexagonal packing array with respect to their design-rule circle.

2. The semiconductor device structure of claim 1, wherein the three or more of the plurality of through-substrate vias that are arranged in a hexagonal packing array have their design-rule circles tangent to one another without overlapping.

3. The semiconductor device structure of claim 2, wherein the plurality of through-substrate vias are grouped into one or more TSV sites on the semiconductor substrate wherein in each of the TSV sites, there are no active integrated circuits in the semiconductor substrate.

4. The semiconductor device structure of claim 1, wherein the plurality of through-substrate vias are grouped into one or more TSV sites on the semiconductor substrate wherein in each of the TSV sites, there are no active integrated circuits in the semiconductor substrate.

5. The semiconductor device structure of claim 1, wherein each through-substrate via has a center and line segments connecting the centers of the three adjacent through-substrate vias form an equilateral triangle.

6. A semiconductor wafer substrate comprising:
an integrated circuit die portion having one or more TSV sites; and
a plurality of through-substrate vias provided in each of the TSV sites, wherein the plurality of through-substrate vias are arranged in a hexagonal packing array with respect to their design-rule circle.

7. The semiconductor wafer substrate of claim 6, wherein the plurality of through-substrate vias that are arranged in a hexagonal packing array have their design-rule circles tangent to one another without overlapping.

8. The semiconductor wafer substrate of claim 7, wherein in each of the TSV sites, there are no active integrated circuits in the semiconductor wafer substrate.

9. The semiconductor wafer substrate of claim 6, wherein in each of the TSV sites, there are no active integrated circuits in the semiconductor wafer substrate.

10. The semiconductor wafer substrate of claim 6, wherein each through-substrate via has a center and line segments connecting the centers of the three adjacent through-substrate vias form an equilateral triangle.
